(19) United States
(12) Patent Application Publication
(10) Pub. No.: US 2005/0270049 A1
(43) Pub. Date: Dec. 8, 2005

(54) Semiconductor device

(75) Inventor: Keisuke Kishishita, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/140,963

(22) Filed: Jun. 1, 2005

(30) Foreign Application Priority Data
Jun. 2, 2004 (JP) P. 2004-164854

(51) Int. Cl. G01R 31/02

(52) U.S. Cl. 324/760

(57) ABSTRACT

It is an object to operate a semiconductor device within a desirable operating temperature range in a normal operation or a test operation.

A semiconductor device 100 comprises a temperature sensor portion 110 for detecting a temperature to output a heat generation instruction when the temperature is equal to or lower than T degree and to output a heat generation stop instruction when the temperature is equal to or higher than T′ degree, and a heat generating portion 120 for performing/stopping the generation of heat in accordance with the heat generation instruction/heat generation stop instruction from the temperature sensor 110. Even if a temperature around the semiconductor device is low, the semiconductor device 100 can be maintained to be a certain temperature or more without an influence thereof. When the temperature around the semiconductor device rises, moreover, heat is not generated. Consequently, it is possible to prevent a malfunction from being caused at a high or low temperature.

### BACKGROUND OF THE INVENTION

1. Field of the Invention

The present invention relates to a semiconductor device.

2. Description of the Related Art

In recent years, a semiconductor has been used for various electric apparatuses with the progress of semiconductor technology. For example, electric apparatuses using a semiconductor also utilize various environments, for example, the signal processing portion of a portable communication terminal, the engine electronic control portion of a car, the image processing portion of an artificial satellite and the image sensor portion of a medical instrument.

A semiconductor is to be designed in order to be normally operated under the condition of a temperature in an environment to be used. By designing the semiconductor to be normally operated within a temperature range which is as wide as possible, it is possible to use electric apparatuses under the condition of various temperatures. For example, a household video camera mounting a semiconductor designed to be normally operated at −40° C. to 120° C. cannot be used in an outer space. By designing the semiconductor to be normally operated up to the vicinity of an absolute zero point, however, it is possible to use the semiconductor in the outer space.

Although a convenience for using electric apparatuses in various environments has been increased, thus, it is very hard to design a semiconductor. The reason is as follows. Since the electrical characteristics of the semiconductor are greatly changed depending on a temperature, a great deal of developing time and cost are required for designing the semiconductor to be normally operated under the condition of all temperatures to be supposed. If the use of the semiconductor is restricted to the condition of a change in a temperature which is as small as possible, the design can easily be carried out so that the cost can also be reduced. For this reason, there has been demanded a technique in which a semiconductor continuously maintains a constant temperature range even if the condition of a temperature around the semiconductor is changed.

FIG. 17 is a block diagram showing the structure of a portion for detecting a temperature and carrying out heating in a conventional semiconductor device. The semiconductor device shown in FIG. 17 is constituted by a control/detecting signal line 1, a heating circuit 10, a detecting circuit 20, an on-chip control circuit 30, a power terminal 40 and a ground terminal 50. The conventional semiconductor device has been devised to be maintained at a high temperature in burn-in to be one of reliability tests for a semiconductor (for example, see JP-A-6-88854 Publication (Page 3, FIG. 1)). A temperature is detected by a temperature detection signal sent from external detecting means (not shown) through the control/detecting signal line 1 or the detecting circuit 20, and a control to turn ON/OFF the heating circuit 10 for heating a chip is carried out by a control signal sent from external control means (not shown) through the control/detecting signal line 1 or the on-chip control circuit 30. By this structure, the temperature of the semiconductor is raised to make high temperature worst conditions, thereby carrying out the test.

If a semiconductor device to be operated normally is to be fabricated also on the conditions of a temperature within a very wide range, a design is to be carried out in consideration of a change in a characteristic depending on the temperature of a transistor within a whole temperature range. For this reason, a very long time is required for a timing design, and furthermore, an area is increased. In general, therefore, a delay slow condition that a delay time in the propagation of a signal within the semiconductor device is maximized and a delay fast condition that a delay time is minimized are set in consideration of an operating temperature, a supply voltage and a process condition and the semiconductor device is designed to satisfy the conditions.

However, the signal propagation delay time of a cell with a conventional transistor length of approximately 0.18 μm generation under a high temperature and low supply voltage condition is set into the delay slow condition with the microfabrication of a process. When the supply voltage is dropped in the vicinity of 0.13 μm generation, a cell having a low temperature delay slow condition appears. The cell serves to combine transistors, thereby creating a logic. A cell base design to implement a function by the combination of the cells has widely been used in the semiconductor device.

In the technique disclosed in JP-A-6-88854 Publication (Page 3, FIG. 1), the temperature of a semiconductor device is maintained to be high and constant during a test. Conventionally, it has been supposed that a high temperature condition is set into the delay slow condition. Under such circumstances, therefore, whether a normal operation is carried out is tested. In some cases, however, the delay slow condition is not set into the high temperature condition but a low temperature condition as described above. With the conventional structure, the test is not carried out on the assumption that the delay slow is brought at a low temperature in the normal operation using a semiconductor for an original function. When the semiconductor device is exposed to a low temperature environment exceeding an operation guarantee range in a normal operation, the semiconductor device might malfunction.

FIGS. 18 and 19 are two graphs showing a relationship between a supply voltage and a delay value in a cell under a low temperature condition and a high temperature condition. In particular, FIG. 18 shows the case in which a transistor length is 0.18 μm generation and FIG. 19 shows the case in which the transistor length is 0.13 μm generation. While the delay value is increased at an almost equal rate under both the low and high temperature conditions when the supply voltage is dropped in FIG. 18, the delay value under the low temperature condition exceeds the delay value under the high temperature condition at a supply voltage Va because of a high change rate in the delay value under the low temperature condition when the supply voltage is dropped in FIG. 19. More specifically, when the supply voltage of Va or less is set to be the worst condition of a low voltage in the cell, the delay slow condition is not set into a high temperature but a low temperature.

Also in the 0.13 μm generation, however, some cells have the delay slow condition maintained at the high temperature as shown in FIG. 18. Accordingly, the delay slow condition which can be uniquely set in the conventional art is varied depending on the cell. Consequently, the delay slow condition cannot be determined uniquely so that it is hard to design a semiconductor device.

In order to solve the problem, there has generally been known a mechanism for providing an apparatus to generate heat on the outside of a semiconductor device, thereby heating the semiconductor device. In order to install the apparatus for generating heat, a space is required. For this reason, the mechanism is not suitable for a small-sized portable electronic apparatus such as a cell phone. Moreover, it is impossible to avoid an increase in a cost due to an increase in the number of components.

In the case in which the apparatus for generating heat is provided on the outside of the semiconductor device, thereby heating the semiconductor device, moreover, a substance around the semiconductor device is heated. Consequently, the semiconductor device is heated indirectly so that a heating efficiency is low.

### SUMMARY OF THE INVENTION

The invention has been made in consideration of the circumstances and has an object to provide a semiconductor device which can be operated within a desirable operating temperature range in a normal operation or a test operation.

In order to solve the problems, the invention comprises temperature detecting means for outputting a control signal to give an instruction for heat generation or non-heat generation based on a temperature of a semiconductor device which is detected in a normal operation, and heat generating means to be brought into a heat generation state or a non-heat generation state in response to the control signal.

In the invention, a control signal for giving an instruction for heat generation is output when the temperature of the semiconductor device is equal to or lower than a first threshold temperature, and a control signal for giving an instruction for non-heat generation is output when the temperature of the semiconductor device is equal to or higher than a second threshold temperature which is equal to or higher than the first threshold temperature.

In the invention, the temperature detecting means outputs a control signal based on a test mode signal upon receipt of the test mode signal from an outside of the semiconductor device in a test operation.

### ADVANTAGE OF THE INVENTION

According to the invention, even if a temperature around the semiconductor device is low or high, the semiconductor device can be maintained within a constant temperature range without an influence thereof. Consequently, it is possible to prevent the malfunction of the semiconductor device from being caused by a change in the temperature.

Moreover, the maintenance of the temperature of the semiconductor device to be equal to or higher than a certain temperature and to be equal to or lower than a certain temperature is linked to the fact that a temperature range to be guaranteed in the design of the semiconductor device can be reduced. Consequently, a timing design can be carried out remarkably easily, and a design man-hour can be shortened and the area of the semiconductor device can be reduced.

Furthermore, the heat generating means is provided in the semiconductor device. Consequently, it is possible to first carry out heating in the semiconductor device efficiently and to reduce a time and a cost which are required for the heating. Moreover, it is not necessary to provide an apparatus for generating heat on the outside of the semiconductor device. Therefore, a very small increase in the area of the semiconductor device is enough. Consequently, the cost can be reduced. In addition, it is possible to reduce the cost by a decrease in the number of components.

Moreover, the temperature detecting means and the heat generating means can be used also in a test operation for guaranteeing the quality of the semiconductor device in addition to the normal operation. Therefore, it is possible to prevent an increase in the area of the semiconductor device. In the test operation for evaluating the reliability of the semiconductor device such as burn-in, moreover, it is possible to bring a state in which the semiconductor device is burned in if the heat generating means is caused to generate heat in order to stabilize the semiconductor device at a high temperature. Consequently, the heat generating means can be shared without the necessity of separate provision for the normal operation and the test operation. Therefore, it is possible to prevent an increase in the area. Furthermore, an expensive furnace for heating the necessary semiconductor device for the burn-in is not required so that the cost can be reduced.

In addition, a plurality of heat generating means is provided. Consequently, the semiconductor device can be heated efficiently in a short time.

Moreover, plural sets of temperature detecting means and heat generating means are provided. Also in a portion in which the temperature falls or rises locally in the semiconductor device, if the temperature detecting means are scattered in the semiconductor device, a local low temperature can be detected and the same portion can be heated by the heat generating means, for example. Therefore, a fine temperature control can be carried out and a malfunction can be prevented from being caused by the low or high temperature of the semiconductor device.

Furthermore, the heat generation wiring is toggled at a clock frequency. Consequently, a large current flows to the resistor of the heat generation wiring so that the inside of the semiconductor device can be first heated efficiently.

In addition, the heat generation wiring is provided with a relay through a buffer unit or an inverter unit. Consequently, each of the heat generation wirings obtained by a division can be toggled at the clock frequency and a total current flowing through the heat generation wiring is more increased than that in the case in which the heat generation wiring is not divided. Correspondingly, the amount of heat generation is increased so that more efficient heating can be carried out.

Moreover, the heat generation wiring is shielded with a wiring connected to a power supply or a ground. Even if the transition of the electric potential of the heat generation wiring is carried out to make a noise, consequently, it is possible to perform a stable circuit operation without an influence on other wirings.

Furthermore, a transistor is connected to the heat generation wiring to cause a source current or a connector current to flow. Consequently, a corresponding current flows to the heat generation wiring so that a heat generation efficiency can be more increased than that in the case in which only the heat generation wiring is provided.

In addition, a material having a resistance value which is equal to or smaller than that of a metal forming the wiring layer of the semiconductor device is used as the heat generation wiring. In the case in which a supply voltage is constant, consequently, a large current flows to the heat generation wiring. Therefore, it is possible to generate more heat in a short time.

Even if a temperature around the semiconductor device falls suddenly, moreover, the temperature detecting means detects the fall so that the heat generating means generates heat to heat the semiconductor device. Consequently, the temperature can be controlled more rapidly so that the malfunction of the semiconductor device can be prevented from being caused by the low temperature. Even if the temperature around the semiconductor device rises rapidly, similarly, the temperature sensor detects the rise so that a heat generating mechanism stops the heat generation. Consequently, the malfunction of the semiconductor device can be prevented from being caused by the high temperature.

### BRIEF DESCRIPTION OF THE DRAWINGS

FIG. 1 is a block diagram showing the structure of a portion for detecting a temperature and carrying out heating in a semiconductor device according to a first embodiment of the invention,

FIG. 2 is a circuit diagram showing the heat generating portion of the semiconductor device in FIG. 1,

FIG. 3 is a circuit diagram showing a variant of the heat generating portion of the semiconductor device in FIG. 1,

FIG. 4 is a circuit diagram showing a variant of the heat generating portion of the semiconductor device in FIG. 1,

FIG. 5 is a correlation chart showing a temperature and a supply voltage in the semiconductor device of FIG. 1,

FIG. 6 is a correlation chart showing the temperature and the supply voltage in the semiconductor device of FIG. 1,

FIG. 7 is a block diagram showing the structure of a portion for detecting a temperature and carrying out heating in a semiconductor device according to a second embodiment of the invention,

FIG. 8 is a block diagram showing the structure of a portion for detecting a temperature and carrying out heating in a semiconductor device according to a third embodiment of the invention,

FIG. 9 is a block diagram showing the structure of a portion for detecting a temperature and carrying out heating in a semiconductor device according to a fourth embodiment of the invention,

FIG. 10 is a circuit diagram showing the heat generating portion of a semiconductor device according to a fifth embodiment of the invention,

FIG. 11 is a circuit diagram showing the heat generating portion of a semiconductor device according to a sixth embodiment of the invention,

FIG. 12 is a circuit diagram showing a variant of the heat generating portion of the semiconductor device in FIG. 11,

FIG. 13 is a circuit diagram showing the heat generating portion of a semiconductor device according to a seventh embodiment of the invention,

FIG. 14 is a circuit diagram showing the heat generating portion of a semiconductor device according to an eighth embodiment of the invention,

FIG. 15 is a circuit diagram showing the heat generating portion of a semiconductor device according to a ninth embodiment of the invention,

FIG. 16 is a block diagram showing the schematic structure of a semiconductor set system according to a tenth embodiment of the invention,

FIG. 17 is a block diagram showing the structure of a portion for detecting a temperature and carrying out heating in a conventional semiconductor device,

FIG. 18 is a chart showing a relationship between a supply voltage and a delay value in 0.18 μm generation in the conventional semiconductor device, and

FIG. 19 is a chart showing a relationship between a supply voltage and a delay value in 0.13 μm generation in the conventional semiconductor device.

### DESCRIPTION OF THE PREFERRED EMBODIMENTS

### First Embodiment

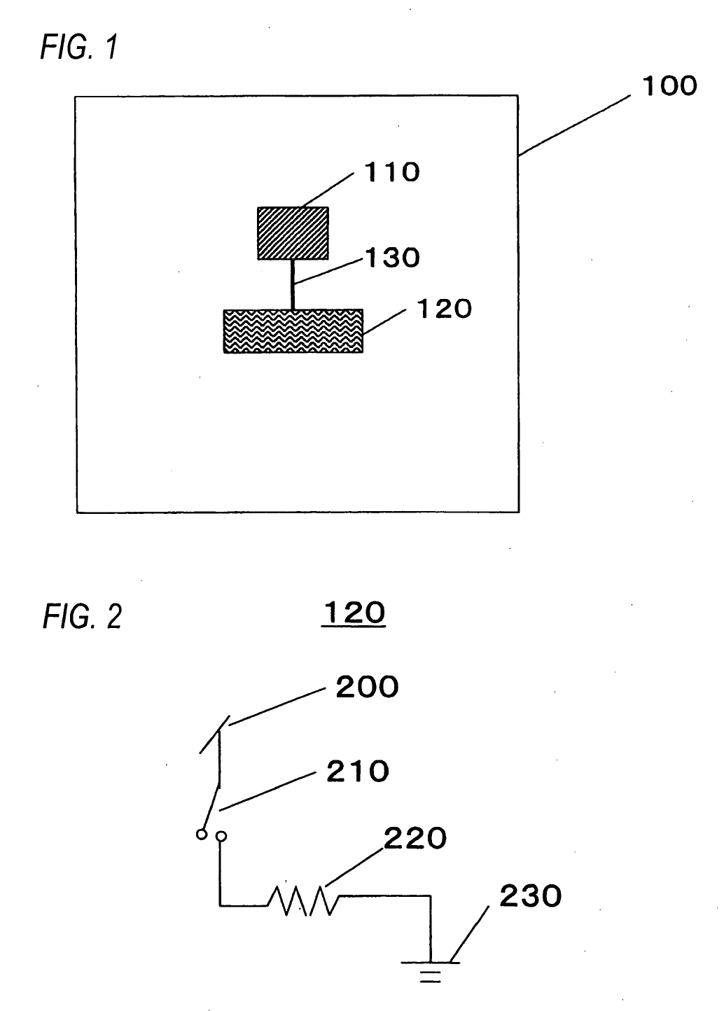

FIG. 1 is a block diagram showing the structure of a portion for detecting a temperature and carrying out heating in a semiconductor device according to a first embodiment of the invention. In FIG. 1, a semiconductor device 100 according to the embodiment comprises a temperature sensor portion (temperature detecting means) 110, a heat generating portion (heat generating means) 120 and a control wiring 130. The temperature sensor 110 and the heat generating portion 120 are electrically connected to each other through the control wiring 130.

The temperature sensor portion 110 includes a diode and a transistor which have temperature characteristics, and outputs a heat generation instruction to the control wiring 130 when a temperature is equal to or lower than T degree in the normal operation of the semiconductor device 100, and outputs a non-heat generation instruction to the control wiring 130 when the temperature is equal to or higher than T′ degree (T′≧T). An example of the structure of a temperature sensor using a transistor has also been disclosed in the Patent Document 1 and can be implemented by the same structure. The heat generating portion 120 generates heat upon receipt of the heat generation instruction from the temperature sensor portion 110 and stops the generation of heat upon receipt of the non-heat generation instruction.

The heat generating portion 120 is constituted to include a switch 210 and a heat generation wiring 220 as shown in FIG. 2, for example, and the switch 210 has one of ends connected to a supply voltage side 200 and the other end connected to one of the ends of the heat generation wiring 220. The other end of the heat generation wiring 220 is connected to a ground side 230. The heat generation wiring 220 is formed by an electric conductor having a small resistance value, and is formed of copper of the wiring layer of the semiconductor device 100, for example. The material of the heat generation wiring 220 described herein is taken as an example, and another material may be used corresponding to a desirable heat generating efficiency. The switch 210 is ON/OFF controlled by the temperature sensor 110, and is turned ON upon receipt of the heat generation instruction and is turned OFF upon receipt of the non-generation instruction.

In the case in which the heat generation wiring 220 is caused to generate heat, the amount of the generation of heat per unit time is proportional to a power consumed by the wiring. If a power is represented as P, P=V²/R can be expressed. When a supply voltage V is constant, therefore, the power P is inversely proportional to a resistance value R. In other words, when the resistance value R of the wiring is smaller, the amount of generation of heat per unit time is larger. In the case in which the supply voltage is constant, thus, a current flows to the heat generation wiring 220 having a small resistance value. Consequently, the heat generation wiring 220 generates heat so that the inside of the semiconductor device can be first heated efficiently.

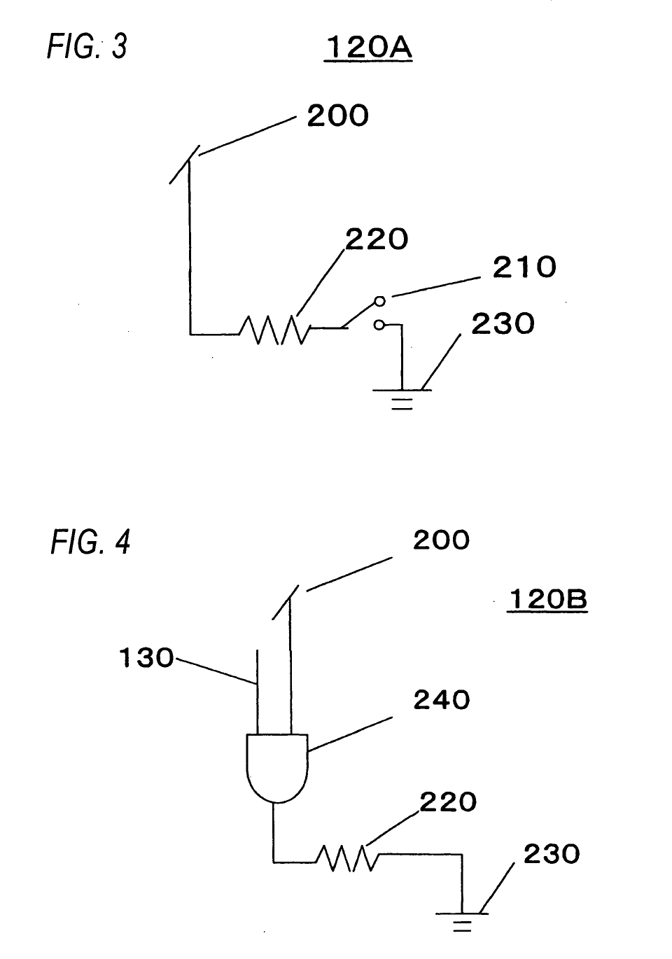

The heat generating portion 120 may have the switch 210 provided between the heat generation wiring 220 and the ground side 230 as shown in FIG. 3. Furthermore, the switch 210 may be implemented by an AND (logical product) unit 240 as shown in FIG. 4 and it is also possible to use a unit other than the AND unit which serves as the switch and constitutes the switch.

Thus, the semiconductor device 100 comprises the temperature sensor portion 110 for detecting a temperature to output a heat generation instruction when the temperature is equal to or lower than T degree and to output a heat generation stop instruction when the temperature is equal to or higher than T′ degree, and the heat generating portion 120 for performing/stopping the generation of heat in accordance with the heat generation instruction or heat generation stop instruction from the temperature sensor portion 110. Even if the temperature around the semiconductor device is low, therefore, the semiconductor device 100 can be maintained to be a constant temperature or more without the influence thereof. When the temperature around the semiconductor device rises, moreover, a mechanism for detecting the rise in the temperature to generate heat can be prevented from generating heat. Therefore, it is possible to maintain the temperature to be constant or less without the semiconductor device 100 rising unnecessarily. By this structure, accordingly, it is possible to prevent the malfunction at the high or low temperature.

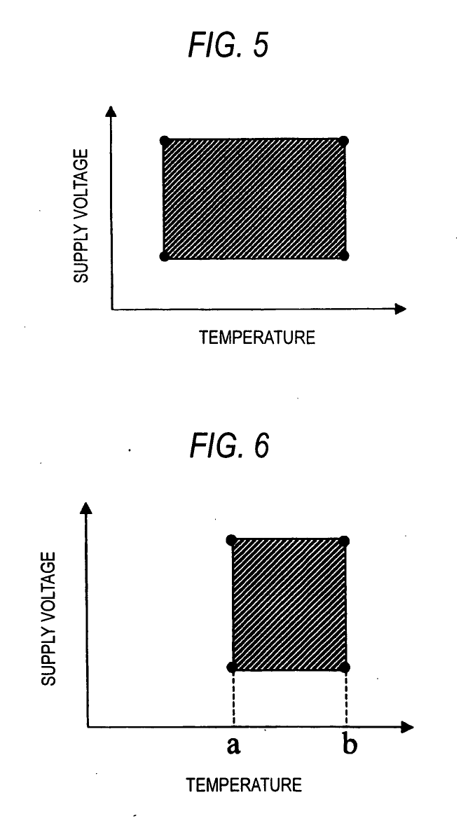

When the semiconductor is to be designed, moreover, a simulation is carried out to decide whether or not a signal satisfies a timing restriction and is thus propagated on the condition of various combinations of the temperature and the supply voltage. FIG. 5 is a chart showing the combination of the temperature and the supply voltage, and a simulation on the condition of four corners of a slant line region is generally carried out to decide whether the timing restriction is satisfied or not.

By the structure according to the embodiment, the slant line region is reduced if the semiconductor device is set to have a temperature which is equal to or higher than “a” degree and is equal to or lower than “b” degree as shown in FIG. 6. When the area of the slant line region is small, a timing restriction can be satisfied more easily. Therefore, the design can be carried out remarkably easily. Moreover, a condition that the delay value of a cell forming a logic by combining transistors is maximized is also obtained uniquely. Therefore, the easiness of the design can be enhanced. As a result, a design man-hour can be shortened and the area can be reduced.

Moreover, the heat generating portion 120 is provided in the semiconductor device 100. Consequently, the heat generating device is not required on the outside of the semiconductor device 100. Consequently, mounting on a small-sized portable electronic apparatus such as a cell phone can be carried out, and furthermore, a cost can be reduced by a decrease in the number of components. Furthermore, the inside of the semiconductor device 100 can be first heated efficiently. Therefore, the time and cost required for heating can be more reduced as compared with the case in which the heating is first carried out on the outside indirectly.

### Second Embodiment

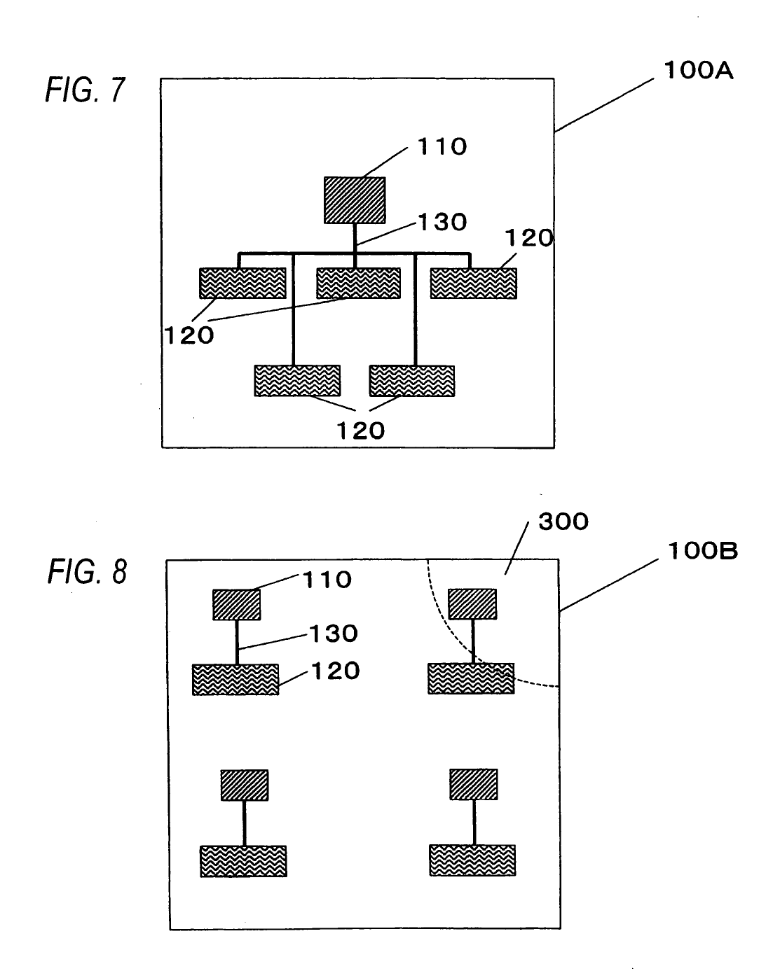

FIG. 7 is a block diagram showing the structure of a portion for detecting a temperature and carrying out heating in a semiconductor device according to a second embodiment of the invention. In FIG. 7, a semiconductor device 100A according to the embodiment comprises a plurality of heat generating portions 120 and these are connected to a common temperature sensor portion 110. By providing the heat generating portions 120, the temperature sensor 110 can detect a situation in which the semiconductor device 100A is cooled suddenly if any. Consequently, the heating is carried out quickly by the heat generating portions 120 so that the temperature of the semiconductor device 100A can be maintained to be constant or more and a malfunction can be prevented from being caused by a low temperature.

### Third Embodiment

FIG. 8 is a block diagram showing the structure of a portion for detecting a temperature and carrying out heating in a semiconductor device according to a third embodiment of the invention. In FIG. 8, a semiconductor device 100B according to the embodiment has a plurality of combinations of a temperature sensor portion 110 and a heat generating portion 120 connected thereto.

The combinations of the temperature sensor portion 110 and the heat generating portion 120 are provided in the semiconductor device 100B. Even if the local portion of the semiconductor device 100B, for example, a local region 300 has a low temperature, consequently, the heat generating portion 120 in or in the vicinity of the local region 300 generates heat so that the semiconductor device 100B can be heated. Even if a temperature in the local region 300 rises in a state in which the heat generating portion 120 generates heat, moreover, a local rise in the temperature can be prevented when the temperature sensor portion 110 in or in the vicinity of the local region 300 detects the rise to send a non-heat generation instruction to the heat generating portion 120 so that the heat generating portion 120 stops the generation of heat. In other words, a finer temperature control can be carried out. Therefore, it is possible to prevent a malfunction from being caused by the low or high temperature of the semiconductor device 100B.

While only one heat generating portion 120 is connected to the temperature sensor 110 in FIG. 8, it is also possible to employ a structure in which a plurality of heat generating portions 120 is connected to one temperature sensor 110.

### Fourth Embodiment

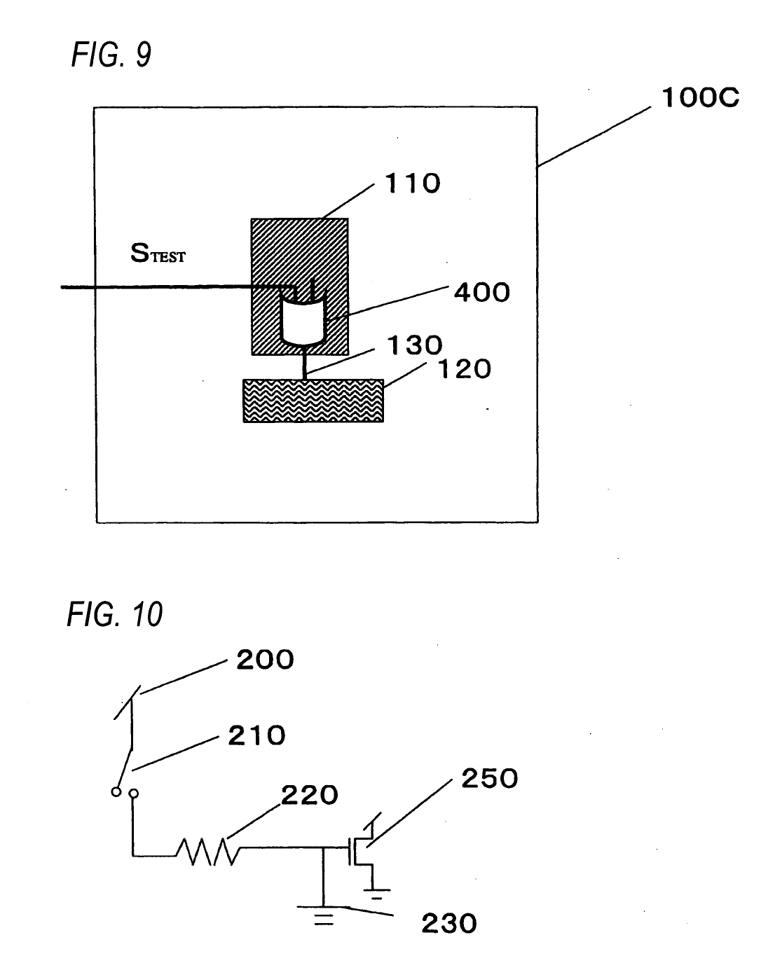

FIG. 9 is a block diagram showing the structure of a portion for detecting a temperature and carrying out heating in a semiconductor device according to a fourth embodiment of the invention. In FIG. 9, a semiconductor device 100C according to the embodiment comprises a temperature sensor portion 110, a heat generating portion 120, and an OR (logical sum) unit 400 for sending an output signal by inputting either a test mode signal S_{TEST} or the output signal of a temperature sensor 100. The test mode signal S_{TEST} is supplied from the outside of the semiconductor device 100C at time of a test for bringing the semiconductor device into a high temperature state by burn-in.

Thus, the heat generating portion 120 can be caused to carry out a test operation. For the case in which the heat generating portion 120 is provided separately for a normal operation and the test operation, moreover, they do not need to be provided separately but can be shared. Therefore, it is possible to prevent an increase in the area of the semiconductor device. Moreover, an expensive furnace for heating a necessary semiconductor device for the burn-in is not required so that a cost can be reduced.

### Fifth Embodiment

FIG. 10 is a circuit diagram showing the heat generating portion of a semiconductor device according to a fifth embodiment of the invention. In FIG. 10, a heat generating portion 120C of the semiconductor device according to the embodiment comprises a switch 210, an Nch transistor 250 and a heat generation wiring 220. The Nch transistor 250 has a source connected to a supply voltage side, a drain connected to a ground side, and a gate connected to one of the ends of the heat generation wiring 220. The other end of the heat generation wiring 220 is connected to the supply voltage side through the switch 210.

The Nch transistor 250 is connected to the heat generation wiring 220. When the electric potential of the heat generation wiring 220 is a supply potential, the Nch transistor 250 is turned ON so that a current flows from the source to the drain. Consequently, a current flowing to the heat generation wiring 220 is more increased as compared with the case of FIG. 2, for example. Thus, more heat is generated as compared with the case in which only the heat generation wiring 220 is provided. Therefore, the semiconductor device can be heated efficiently.

Moreover, the heat generating portion 120C has a comparatively simple structure. Therefore, the area of the semiconductor device is simply increased slightly. Consequently, the cost can be reduced. The Nch transistor 250 may be an inverter or another unit (for example, a bipolar transistor).

### Sixth Embodiment

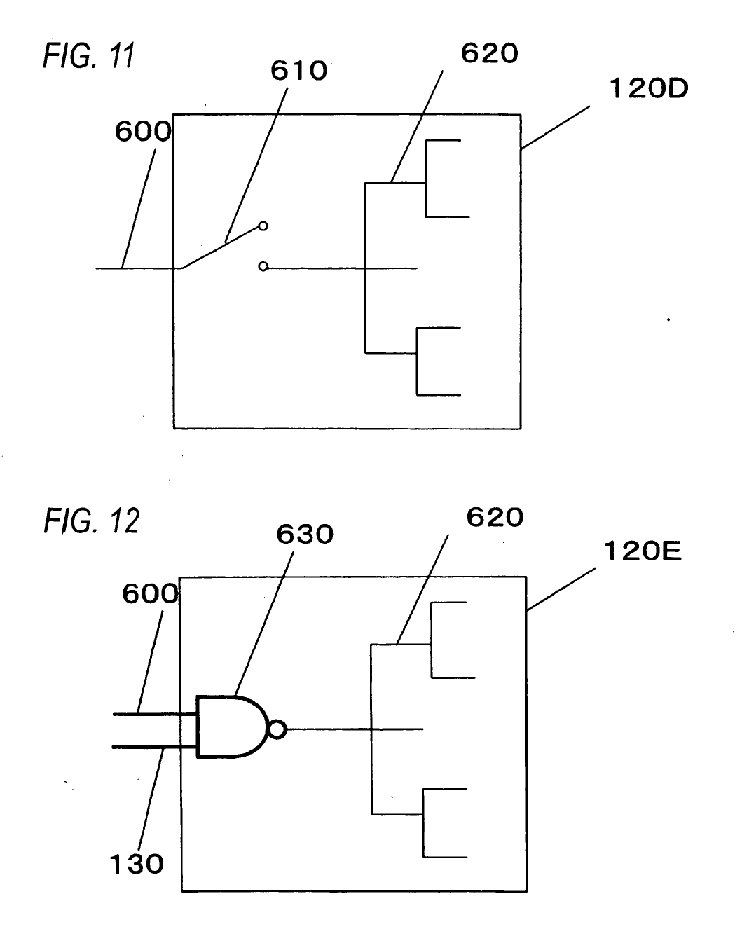

FIG. 11 is a circuit diagram showing the heat generating portion of a semiconductor device according to a sixth embodiment of the invention. In FIG. 11, a heat generating portion 120D of the semiconductor device according to the embodiment comprises a clock wiring (a wiring for transmitting a clock signal) 600, a switch 610, and a heat generation wiring 620. The switch 610 is turned ON/OFF in response to the output signal of a temperature sensor 110 in just the same manner as the switch 210 according to the fifth embodiment. The heat generation wiring 620 is provided like a branch in the semiconductor device.

When the switch 610 is ON, the heat generation wiring 620 is toggled at an equal frequency to the frequency of a clock. Consequently, a large current flows to the resistor of the heat generation wiring 620. Thus, the heat generation wiring 620 generates heat so that the inside of the semiconductor device can be first heated efficiently.

Moreover, the heat generating portion 120D has a comparatively simple structure. Therefore, a very small increase in the area of the semiconductor device is enough. Consequently, a cost can be reduced. Since the switch 610 is turned ON/OFF, it is also possible to employ any switch which can be mounted on the semiconductor device. For example, in a heat generating portion 120E shown in FIG. 12, the switch is implemented by an NAND unit 630.

### Seventh Embodiment

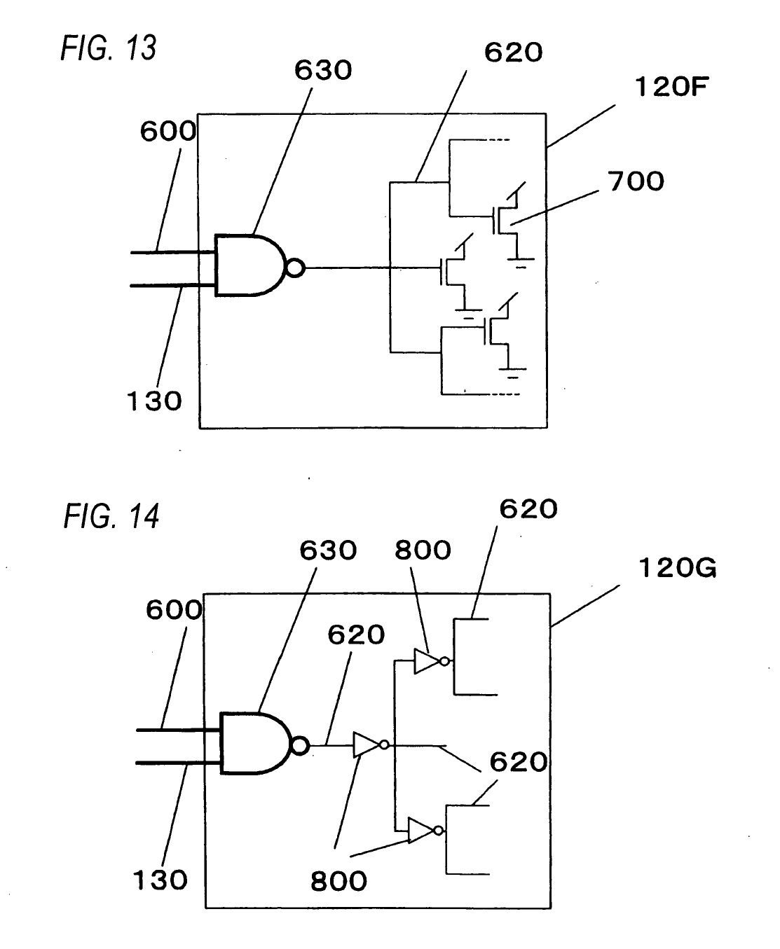

FIG. 13 is a circuit diagram showing the heat generating portion of a semiconductor device according to a seventh embodiment of the invention. In FIG. 13, a heat generating portion 120F of the semiconductor device according to the embodiment comprises a control wiring 130, a clock wiring 600, an NAND unit 630, a heat generation wiring 620, and an Nch transistor 700. The Nch transistor 700 has a source connected to a supply voltage side, a drain connected to a ground side, and a gate connected to the heat generation wiring 620.

The Nch transistor 700 is connected to the heat generation wiring 620 so that a current flows from a source to a drain in the Nch transistor 700 by the toggle of the heat generation wiring 620. Consequently, there is generated more heat than that in the case in which only the heat generation wiring 620 is provided. Therefore, the semiconductor device can be heated efficiently. The Nch transistor 620 may be an inverter or another unit (for example, a bipolar transistor).

### Eighth Embodiment

FIG. 14 is a circuit diagram showing the heat generating portion of a semiconductor device according to an eighth embodiment of the invention. In FIG. 14, a heat generating portion 120G of the semiconductor device according to the embodiment comprises a control wiring 130, a clock wiring 600, an NAND (exclusive AND) unit 630, a heat generation wiring 620, and an inverter unit 800. The inverter unit 800 is inserted into each heat generation wiring 620 obtained by a division, and the heat generation wiring 620 is thus driven. By inserting the inverter unit 800 through the heat generation wiring 620, a larger current can be caused to flow as compared with the case in which the heat generation wiring 620 is not divided. Consequently, the heat generation wiring 620 can generate heat better. Thus, the semiconductor device can be heated efficiently. As a matter of course, it is also possible to use a buffer unit in addition to the inverter unit 800.

### Ninth Embodiment

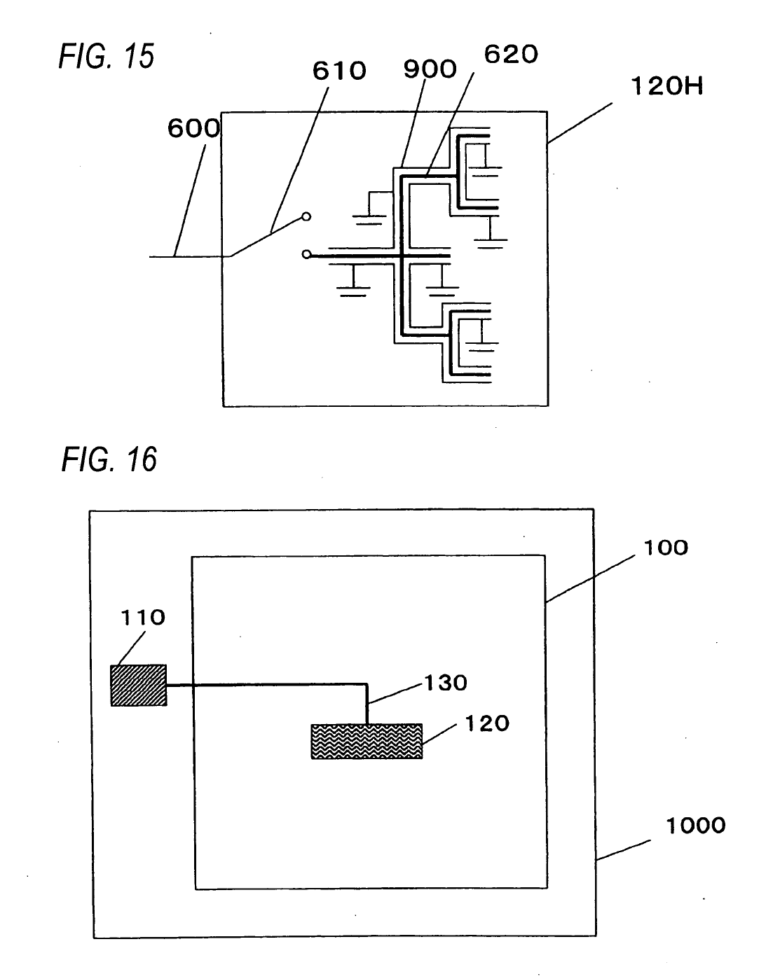

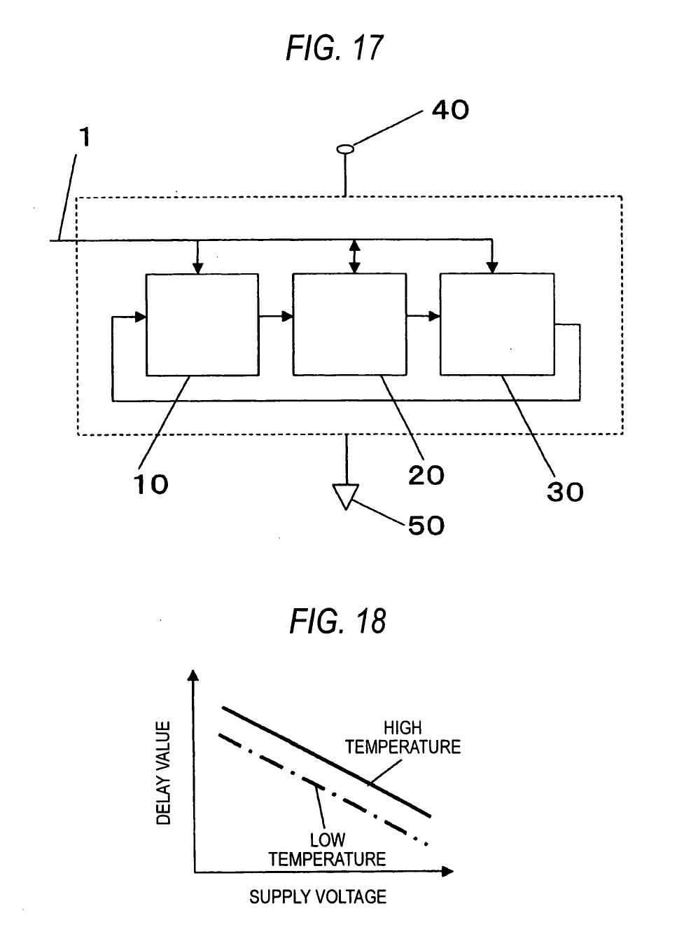

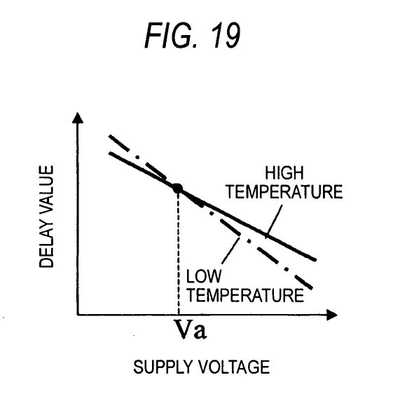

FIG. 15 is a circuit diagram showing the heat generating portion of a semiconductor device according to a ninth embodiment of the invention. In FIG. 15, a heat generating portion 120H of the semiconductor device according to the embodiment comprises a clock wiring 600, a switch 610, a heat generation wiring 620 and a shield wiring 900. The shield wiring 900 is connected to a ground. The shield wiring 900 is provided in parallel with the heat generation wiring 620 in the same wiring layer.

The shield wiring 900 is provided. Even if the transition of the electric potential of the heat generation wiring 620 is performed to make a noise, therefore, other wirings are not influenced because shielding is carried out by the shield wiring 900. Consequently, it is possible to implement a stable circuit operation.

While a shield wiring in the same layer as the heat generation wiring 620 is shown in FIG. 15, the advantages of the shield can further be obtained when shield wirings to be provided in parallel in upper and lower layers are given.

### Tenth Embodiment

FIG. 16 is a block diagram showing the schematic structure of a semiconductor set system according to a tenth embodiment of the invention. In FIG. 16, a semiconductor set system 1000 according to the embodiment comprises a semiconductor device 100 having a heat generating portion 120 and a control wiring 130, and a temperature sensor portion 110 provided on the outside of the semiconductor device 100 and connected electrically to the control wiring 130 of the semiconductor device 100, thereby giving a heat generation command or a heat generation stop command to the heat generating portion 120 of the semiconductor device 100.

The temperature sensor portion 110 is provided on the outside of the semiconductor device 100. Even if a temperature around the semiconductor device 100 falls suddenly, for example, the fall is detected to give a heat generation instruction to the heat generating portion 120. Consequently, a temperature control can be carried out more rapidly. Thus, it is possible to prevent a malfunction from being caused by the low or high temperature of the semiconductor device 100.

As a matter of course, the first to tenth embodiments can also be combined with others as much as possible in addition to a single implementation.

Even if a temperature around the semiconductor device according to the invention is low or high, the semiconductor device can be maintained within a constant temperature range without an influence thereof. Therefore, it is possible to have an advantage that the malfunction of the semiconductor device can be prevented from being caused by a change in the temperature. Thus, the semiconductor device is useful for a semiconductor device to be utilized under a wide temperature condition.

1. A semiconductor device, comprising:
a temperature detector, outputting a control signal to give an instruction for heat generation or non-heat generation based on a temperature of the semiconductor device which is detected in a normal operation; and
a heat generator, to be brought into a heat generation state or a non-heat generation state in response to the control signal.

2. The semiconductor device according to claim 1, wherein the temperature detector outputs a control signal for giving an instruction for heat generation when the temperature of the semiconductor device is equal to or lower than a first threshold temperature, and outputs a control signal for giving an instruction for non-heat generation when the temperature of the semiconductor device is equal to or higher than a second threshold temperature which is equal to or higher than the first threshold temperature.

3. The semiconductor device according to claim 1 or 2, wherein the temperature detector outputs a control signal based on a test mode signal upon receipt of the test mode signal from an outside of the semiconductor device in a test operation.

4. The semiconductor device according to any of claims 1 to 3, wherein a plurality of the heat generators is provided and the temperature detector gives a control signal to each of the heat generator.

5. The semiconductor device according to any of claims 1 to 3, wherein plural sets of the temperature detector and the heat generator are provided, each of the sets being disposed evenly in the semiconductor device.

6. The semiconductor device according to any of claims 1 to 5, wherein the heat generator comprises:
a heat generation wiring, formed by an electric conductor; and
a switch, which is brought into an ON state when a control signal for giving an instruction for heat generation is input and is brought into an OFF state when a control signal for giving an instruction for non-heat generation is input,
a current being supplied to the heat generation wiring when the switch is brought into the ON state.

7. The semiconductor device according to any of claims 1 to 5, wherein the heat generator comprises:
a heat generation wiring formed by an electric conductor; and
a switch which has one of ends connected to a wiring for transmitting a clock signal in the semiconductor device and the other end connected to the heat generation wiring, and is brought into an ON state when a control signal for giving an instruction for heat generation is input and is brought into an OFF state when a control signal for giving an instruction for non-heat generation is input,
a clock signal being supplied to the heat generation wiring through the switch when the switch is brought into the ON state.

8. The semiconductor device according to claim 7, wherein the heat generation wiring takes a shape of branches, and
the switch is constituted by a 2-input exclusive AND gate, the exclusive AND gate has one of input ends to which the temperature detector is connected and the other input end to which the wiring for transmitting a clock signal is connected, and furthermore, an output end of the exclusive AND gate is connected to the heat generation wiring.

9. The semiconductor device according to any of claims 6 to 8, wherein the heat generator includes either a buffer unit or an inverter unit which is wired to relay the heat generation wiring.

10. The semiconductor device according to any of claims 6 to 9, wherein the heat generator includes a shield wiring for shielding the heat generation wiring with a wiring connected to a power supply or a ground.

11. The semiconductor device according to any of claims 6 to 10, wherein the heat generator has a transistor having a gate terminal or a base terminal connected to a tip of the heat generation wiring, and a source current or a collector current flows to the transistor depending on an electric potential of the heat generation wiring.

12. The semiconductor device according to any of claims 6 to 11, wherein the heat generator includes the heat generating wiring to be a material having a resistance value which is equal to or smaller than a resistance value of a metal forming a wiring layer of the semiconductor device.

13. A semiconductor set system, comprising:
an external temperature detector, provided on an outside of a semiconductor device and serving to detect a temperature of surroundings of the semiconductor device or a package including the semiconductor device in a normal operation of the semiconductor device; and
the semiconductor device having a heat generator connected electrically to the external temperature detector and brought into a heat generation state or a non-heat generation state depending on a temperature detected by the external temperature detector.
